(19) United States
(12) Patent Application Publication
(10) Pub. No.: US 2007/0290301 A1
(43) Pub. Date: Dec. 20, 2007

(54) Multi-chip stacked package with reduced thickness

(75) Inventor: Hung-Tsun Lin, Tainan (TW)

Correspondence Address: TROXELL LAW OFFICE PLLC;SUITE 1404, 5205 LEESBURG PIKE, FALLS CHURCH, VA, 22041, US

(73) Assignees: ChipMOS Technologies (Bermuda) Ltd.; ChipMOS Technologies Inc.

(21) Appl. No.: 11/601,752

(22) Filed: Nov. 20, 2006

(30) Foreign Application Priority Data
Jun. 20, 2006 (CN) 095122172

(51) Int. Cl. H01L 23/552

(52) U.S. Cl. 257/659

(57) ABSTRACT

A multi-chip stacked package is revealed, primarily comprising a spacer pad and a plurality of leads of a lead frame, a first chip, a second chip, and an encapsulant. A plurality of first electrodes are formed on the active surface of the first chip below the spacer pad and are electrically connected to one surfaces of the leads. A plurality of second electrodes are formed on the active surface of the second chip above the spacer pad and are electrically connected to the same surfaces of the leads. The encapsulant encapsulates the spacer pad, parts of the leads, the first chip, and the second chip where the active surface of the first chip is attached to the bottom surface of the spacer pad and the back surface of the second chip to the top surface of the spacer pad. Moreover, the spacer pad does not cover the first electrodes of the first chip for wire-bonding to achieve multi-chip stacking with a reduced overall package thickness.

### FIELD OF THE INVENTION

The present invention relates to an IC package encapsulating a plurality of semiconductor chips, and more particularly, to a multi-chip stacked package using a lead frame with a reduced thickness.

### BACKGROUND OF THE INVENTION

Multi-chip stacked packages (MCP) is a very mature technology, a plurality of chips are vertically stacked in a package to reduce the dimension of the package. However, the spacers between the chips will increase the overall package thickness.

As shown in FIG. 1, a lead frame is adopted in a conventional multi-chip package 100 as the chip carrier. The package 100 comprises a die pad 111 and a plurality of leads 112 of a lead frame, a first chip 120, a second chip 130, and an encapsulant 140. The first chip 120 and the second chip 130 are stacked vertically on the die pad 111. The bonding pads 122 on the active surface 121 of the first chip 120 and the bonding pads 132 on the active surface 131 of the second chip 130 are electrically connected to the leads 112 by a plurality of bonding wires 150. The back surface of the first chip 120 is attached to the die pad 111. A spacer 160 is disposed between the active surface 121 of the first chip 120 and the back surface of the second chip 130 to avoid some of the first bonding wire 150 contacting with the back surface of the second chip 130. Conventionally, the spacer 160 is an independent component which can be dummy chips, metal sheets, tapes, or resin having spacer balls. Therefore, the thickness of the encapsulant 140 needs to be increased and becomes thicker. When the thickness of the encpasulant 140 is improperly limited, the upper bonding wires 150 may be exposed from the encapsulant 140. Moreover, in order to balance the mold flow during the formation of encapsulant 140, the die pad 111 will need proper downset design due to the thickness of the spacers so that the downset 111 must be lower than the leads 112.

As shown in FIG. 2, another conventional multi-chip package 200 primarily comprises a die pad 211 and a plurality of leads 212 of a lead frame, a first chip 220, a second chip 230, and an encapsulant 240. The back surface of the first chip 220 is attached to the bottom surface of the die pad 211, the back surface of the second chip 230 is attached to the top surface of the die pad 211. The first chip 220 is electrically connected to the leads 212 by a plurality of bonding wires 251. The second chip 230 is electrically connected to the leads 212 by a plurality of bonding wires 252. Therefore, the back surface of the first chip 220 is facing toward the back surface of the second chip 230 to be a back-to-back stacking configuration. During wire bonding of the bonding wires 251 and 252 for electrical connections, the lead frame needs to be flipped over on a special stage. Moreover, two electroplated layers 213 formed on the top surfaces and on the bottom surfaces of the leads 212 are necessary leading to higher lead frames costs, i.e., higher packaging costs. Normally, the adhesion between the encapsulant 240 and the electroplated layer is not good. Therefore, if the covered area of the electroplated layers 213 is too larger, delamination between the encapsulant 240 and the leads 212 will become an issue.

### SUMMARY OF THE INVENTION

The main purpose of the present invention is to provide a multi-chip stacked package where a plurality of chips and parts of the lead frame are encapsulated by the encapsulant. By improving the design of the die pad of a lead frame as a spacer, the chips can be vertically stacked for electrical connections to reduce the thickness of the encapsulant by a thickness of a spacer.

The second purpose of the present invention is to provide a multi-chip stacked package where the lower bonding wires will not contact with the back surface of the upper chip between the vertically stacked chips.

The third purpose of the present invention is to provide a multi-chip stacked package where a die-attaching material is attached and fully covered the back surface of the upper chip to increase the support of a smaller die pad to the upper chip and to avoid the contact of the lower bonding wires to the back surface of the upper chip.

According to the present invention, a multi-chip stacked package primarily comprises a spacer pad and a plurality of leads of a lead frame, a first chip, a second chip, and an encapsulant. The first chip has a first active surface and a first back surface where a plurality of first electrodes are formed on the first active surface and are electrically connected to the leads. The second chip has a second active surface and a second back surface where a plurality of second electrodes are formed on the second active surface and are electrically connected to the leads. An encapsulant encapsulates the spacer pad, parts of the leads, the first chip, and the second chip where the first active surface of the first chip is attached to the bottom surface of the spacer pad and the second back surface of the second chip to the top surface of the spacer pad. Moreover, the spacer pad will not cover the first electrodes of the first chip for wire-bonding.

### DESCRIPTION OF THE DRAWINGS

FIG. 1 shows a cross sectional view of a conventional multi-chip stacked package.

FIG. 2 shows a cross sectional view of another conventional multi-chip stacked package.

FIG. 3 shows a cross sectional view of a multi-chip stacked package according to the first embodiment of the present invention.

FIG. 4 shows a top view of the first chip and the spacer pad from the multi-chip stacked package according to the first embodiment of the present invention.

FIG. 5 shows a cross sectional view of another multi-chip stacked package according to the second embodiment of the present invention.

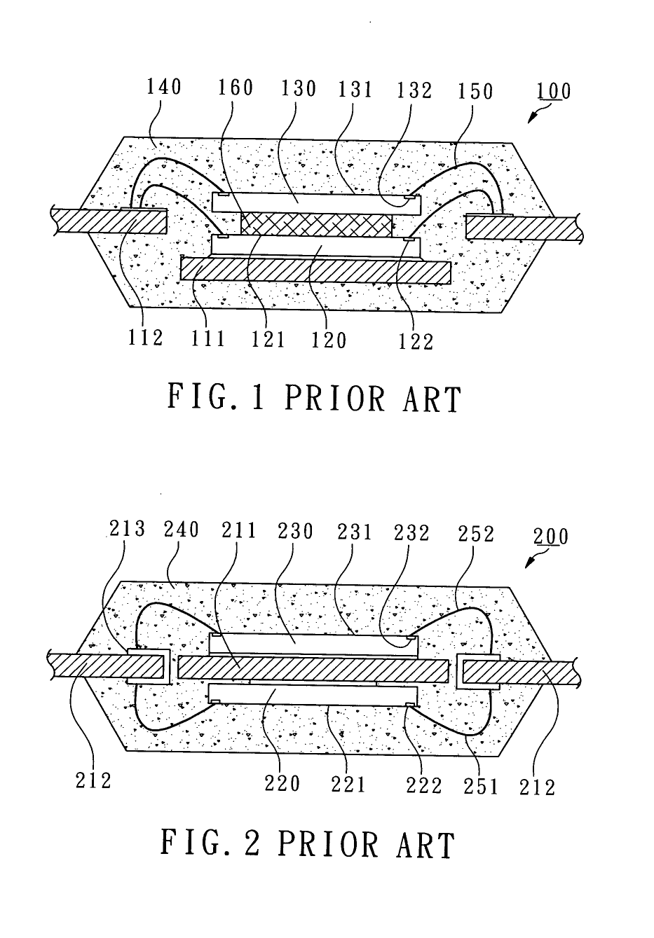

### DETAIL DESCRIPTION OF THE INVENTION

Please refer to the attached drawings, the present invention will be described by means of embodiment(s) below.

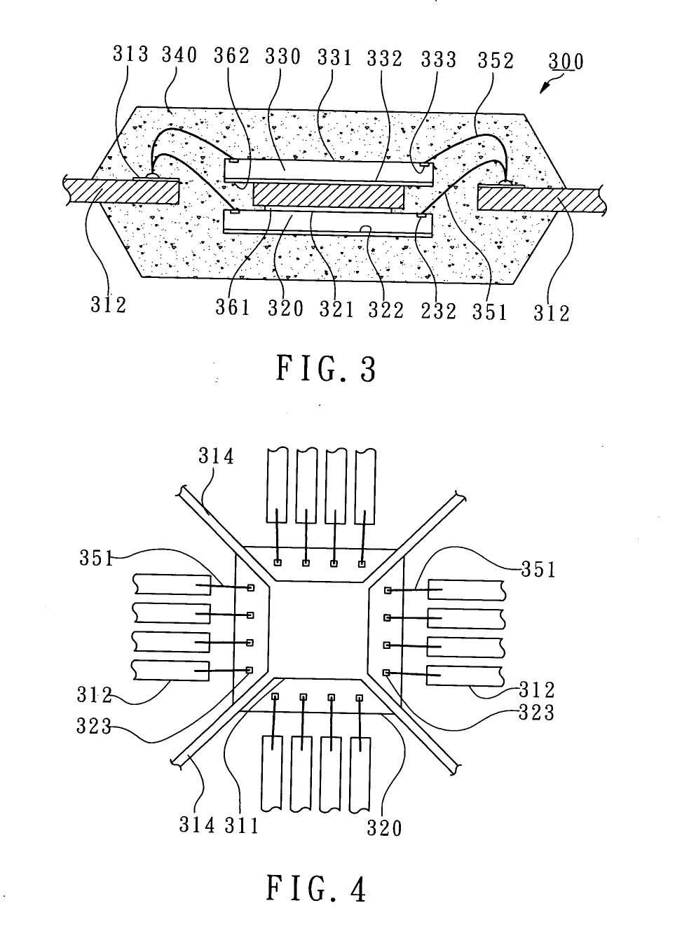

According to the first embodiment of the present invention, a multi-chip stacked package 300 is revealed in FIG. 3, primarily comprising a spacer pad 311 and a plurality of leads 312 of a lead frame, a first chip 320, a second chip 330, and an encapsulant 340 where the spacer pad 311 and the leads 312 are made from a same lead frame which is made by metal such as copper, iron and its alloy. Normally, the shape of the spacer pad 311 is the same as the conventional die pad but smaller.

The first chip 320 has a first active surface 321 and a first back surface 322 where a plurality of electrodes 323 are formed on the active surface 321, for example, bonding pads or bumps. The first electrodes 323 are electrically connected to the leads 312 by a plurality of first bonding wires 351. The second chip 330 has a second active surface 331 and a second back surface 332 where a plurality of second electrodes 333 are formed on the second active surface 331. The second electrodes 333 are electrically connected to the leads 312 by a plurality of bonding wires 352. The electrically connected leads 312 by first bonding wires 351 or by the second bonding wires 352 can be the same leads or different leads. In the present embodiment, the dimensions of the first chip 320 and the second chip 330 are the same, moreover, the first chip 320 and the second chip 330 are vertically stacked with the active surfaces facing upwards. An encapsulant 340 encapsulates the spacer pad 311, parts of the leads 312, the first chip 320, and the second chip 330 where the first active surface 321 of the first chip 320 is attached to the bottom surface of the spacer pad 311 and the second back surface 332 of the second chip 330 to the top surface of the spacer pad 311 to achieve multi-chip vertical stacking. Furthermore, as shown in FIG. 4, the spacer pad 311 will not cover the first electrodes 323 of the first chip 320 so that the first bonding wires 351 are formed for electrical connections during first die attachment. Normally, the spacer pad 351 provides spacing so that the first bonding wires 351 will not contact with the second back surface 332 of the second chip 330.

Therefore, the first chip 320 and the second chip 330 are vertically stacked with the active surfaces facing upward. Moreover, the spacer pad 311 can provide spacing between the first chip 320 and the second chip 330 and also provide die attachment for the first chip 320 and the second chip 330 so that the thickness of the encapsulant 340 can be reduced by a thickness of a spacer.

Preferably, the multi-chip stacked package 300 further comprises a first die-attaching layer 361 and a second die-attaching layer 362 for attaching the first chip 320 and the second chip 330 respectively where the first die-attaching layer 361 partially covers the first active surface 321 of the chip 320 and the second die-attaching layer 362 fully covers the second back surface 332 of the second chip 330. In this embodiment, the spacer pad 311 is smaller with enhanced supports to the second chip 330, moreover, the first bonding wires 351 will not contact with the second back surface 332 of the second chip 330.

As shown in FIG. 3, preferably, the first bonding wires 351 are formed by reverse wire bonding technology, i.e., the first bonding wires 351 have first ball bonds on the leads 312, then dragged to the first electrodes 323 of the first chip 320, and finally formed wedge bonds on the first electrodes 323 of the first chip 320 so that the loop height of the first bonding wires 351 is far away from the first chip 320 without interfering the second die attachment for the second chip 330.

As shown in FIG. 4, in the present embodiment, the first electrodes 323 are formed at the peripheries of the first active surface 321 of the first chip 320. The dimension of the spacer pad 311 is smaller than the first active surface 321 of the first chip 320 so that the first electrodes 323 are exposed and are not covered by the first die-attaching layer 361 after die attachment. A plurality of tie bars 314 are connected to the spacer pad 311 and are extended from the corners of the first active surface 321 so that the first bonding wires 351 can be wire bonded to the first electrodes 323. Preferably, the tie bars 314 are straight without bending so that the spacer pad 311 and the encapsulated parts of the leads 312 are coplanar which can balance the mold flow during encapsulation. Furthermore, an electroplated layer 313, such as Ag, is only formed on the top surfaces of the inner ends of the leads 312 but not on the sidewalls nor on the bottom surfaces of the leads 312 so that the first bonding wires 351 and the second bonding wires 352 can be bonded to the top surfaces of the inner ends of the leads 312. Therefore, there is no need of double electroplating for the lead frame to reduce the cost of the lead frame and to avoid delamination between the leads 312 and the encapsulant 340.

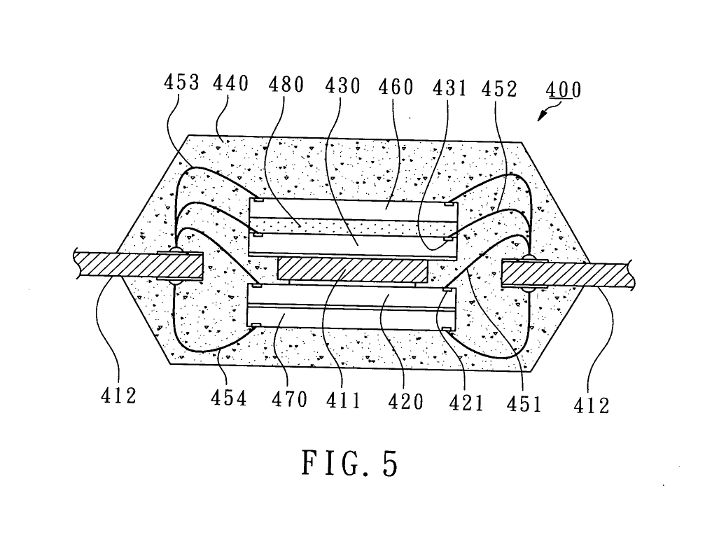

Moreover, the number of stacked chips is not limited in the present invention. According to the second embodiment of the present invention, another multi-chip stacked package 400, as shown in FIG. 5, comprises a spacer pad 411 and a plurality of leads 412 of a lead frame, a first chip 420, a second chip 430, and an encapsulant 340 where the major components of the multi-chip stacked package 400 are the same as the first embodiment except further comprises a third chip 460 and/or a fourth chip 470. A plurality of first electrodes 421 are formed on the first active surface of the first chip 420 and are electrically connected to the leads 412 by a plurality of bonding wires 451. A plurality of second electrodes 431 are formed on the active surface of the second chip 430 and are electrically connected to the leads 412 by a plurality of second bonding wires 452. An encapsulant 440 encapsulates the spacer pad 411, parts of the leads 412, the first chip 420, the second chip 430, the third chip 460, and the fourth chip 470 where the active surface of the first chip 420 is attached to the bottom surface of the spacer pad 411 and the back surface of the second chip 430 to the top surface of the spacer pad 411 to sandwich the spacer pad 411. The spacer pad 411 will not cover the first electrodes 421 of the first chip 420. Therefore, the thickness of the encapsulant 440 can be reduced by saving a thickness of a spacer. Furthermore, the third chip 460 is attached to the active surface of the second chip 430 where a spacer adhesive 480 is formed between the second chip 430 and the third chip 460 such as B-stage encapsulant 440 before curing to avoid the third chip 460 contacting the second bonding wires 452 and to encapsulate one ends of the second bonding wires 452. The third chip 460 is electrically connected to the leads 412 by the third bonding wires 453. The back surface of the fourth chip 470 is attached to the back surface of the first chip 420 to achieve multi-chip stacking with a reduced overall package thickness.

The above description of embodiments of this invention is intended to be illustrative and not limiting. Other embodiments of this invention will be obvious to those skilled in the art in view of the above disclosure.

What is claimed is:

1. A multi-chip stacked package comprising:
a spacer pad and a plurality of leads of a lead frame;
a first chip having a first active surface and a first back surface, wherein a plurality of first electrodes are formed on the first active surface and are electrically connected to the leads;
a second chip having a second active surface and a second back surface, wherein plurality of second electrodes are formed on the second active surface and are electrically connected to the leads, and
an encapsulant encapsulating the spacer pad, parts of the leads, the first chip, and the second chip;
wherein the first active surface of the first chip is attached to the bottom surface of the spacer pad and the second back surface of the second chip to the top surface of the spacer pad, the spacer pad does not cover the first electrodes of the first chip.

2. The multi-chip stacked package of claim 1, further comprising a plurality of first bonding wires electrically connecting the first electrodes of the first chip and the corresponding leads.

3. The multi-chip stacked package of claim 2, wherein the first bonding wires are reverse bonding to have a loop height far away from the first chip and the second chip.

4. The multi-chip stacked package of claim 2, wherein the spacer pad has a thickness so that the first bonding wires will not contact with the second back surface of the second chip.

5. The multi-chip stacked package of claim 1, wherein the dimension of the spacer pad is smaller than the first active surface of the first chip.

6. The multi-chip stacked package of claim 5, wherein the first electrodes are formed at the peripheries of the first active surface of the first chip.

7. The multi-chip stacked package of claim 6, wherein a plurality of tie bars are connected to the spacer pad and are extended from the corners of the first active surface.

8. The multi-chip stacked package of claim 7, wherein the tie bars are straight without bending so that the spacer pad and the encapsulated parts of the leads are coplanar.

9. The multi-chip stacked package of claim 1, further comprising an electroplating layer only formed on the top surfaces of the inner ends of the leads.

10. The multi-chip stacked package of claim 9, wherein the electroplating layer is not formed on the sidewalls nor on the bottom surfaces of the inner ends of the leads.

11. The multi-chip stacked package of claim 1, further comprising a first die-attaching layer and a second die-attaching layer to attach the first chip and the second chip wherein the first die-attaching layer partially covers the first active surface of the first chip and the second die-attaching layer fully covers the second back surface of the second chip.

12. The multi-chip stacked package of claim 1, further comprising a third chip disposed on the second active surface of the second chip.

13. The multi-chip stacked package of claim 12, further comprising a spacer adhesive formed between the second chip and the third chip.

14. The multi-chip stacked package of claim 12, further comprising a fourth chip disposed on the first back surface of the first chip.
